(19) United States
(12) Patent Application Publication
(10) Pub. No.: US 2005/0253240 A1
(43) Pub. Date: Nov. 17, 2005

(54) Micromechanical component and corresponsing production method

(76) Inventors: Wolfgang Nuechter, Tamm (DE); Frank Fischer, Gomaringen (DE); Frieder Haag, Wannweil (DE); Eckhard Graf, Gomringen (DE)

Correspondence Address: KENYON & KENYON, ONE BROADWAY, NEW YORK, NY, 10004, US

(21) Appl. No.: 10/514,364

(22) PCT Filed: Feb. 21, 2003
(86) PCT No.: PCT/DE03/00552

§ 371 Date: Nov. 11, 2004

(30) Foreign Application Priority Data
Jun. 12, 2002 (DE) 10226033.8

(51) Int. Cl. H01L 21/48; H01L 23/28

(52) U.S. Cl. 257/686; 257/787; 438/127; 257/778; 257/777; 438/108

(57) ABSTRACT

A micromechanical component including a chip which is mounted on a substrate and has an encapsulated chip area which is higher than its vicinity, as well as a mounting area provided in the vicinity of the encapsulated chip area. The chip being mounted on the substrate by a mounting arrangement which is connected to the mounting area, so that the encapsulated chip area faces the substrate and is positioned at a distance therefrom. The encapsulated chip area is surrounded by an underfill beneath the chip. A method for the manufacture of the micromechanical component is also provided.

### FIELD OF THE INVENTION

The present invention relates to a micromechanical component which includes a substrate-mounted chip having an encapsulated chip area which is higher than its vicinity and a mounting area provided in the region of the encapsulated chip area, as well as a method for manufacturing the micromechanical component.

### BACKGROUND INFORMATION

The structure of a functional layer system and a method for the hermetic encapsulation of sensors by a surface micromechanical arrangement is discussed in German patent document no. 195 37 814. This publication describes the manufacture of the sensor structure using available technological methods. The above-mentioned hermetic encapsulation is achieved via a separate cap wafer made of silicon, which is structured according to complex structuring processes, for example KOH etching. The cap wafer is applied to the substrate having the sensor (sensor wafer) by glass soldering (seal glass). For this purpose, a wide bonding frame must be provided around each sensor chip to ensure adequate adhesion and sealing of the cap. This greatly limits the number of sensor chips per sensor wafer. The great space requirements and complex cap wafer manufacturing process make the sensor encapsulation very expensive.

An alternative encapsulation technique is discussed in European patent document no. 0 721 587, which refers to a layer structure in which the structured trenches of a micromechanical component, for example a capacitive acceleration sensor, are covered by or filled with an insulating material. A membrane layer is applied to this insulation layer and structured so that window openings are provided over the moving elements of the component structure. The insulating material and a lower sacrificial layer located beneath the functional layer of the component structure are selectively etched through these window openings against the perforated membrane layer and the functional layer. The window openings in the membrane layer are then covered by a cover layer, thereby forming a hermetically sealed cavity above the moving elements. This cavity can be supported on fixed sensor areas to improve mechanical stability.

A further alternative encapsulation technique is presented in U.S. Pat. No. 5,919,364. According to this method, a thin gas-permeable polysilicon membrane is used as the membrane layer, which can be penetrated by the reactants during etching of the sacrificial layer.

All methods described above are based on the principle of covering the functional elements of the sensor with a further upper sacrificial layer, which is selectively etched against the functional elements after applying a structured membrane layer. The moving parts of the sensor are exposed during this process. This principle has been presented in a modified form, for example in “Electrostatically Driven Vacuum-Encapsulated Polysilicon Resonators: Part I. Design and Fabrication”, R. Legtenberg et al., Sensors and Actuators A 45 (1994), 57, “The Application of Fine-Grained, Tensile Polysilicon to Mechanically Resonant Transducers”, H. Guckel et al., Sensors and Actuators A 21-23 (1990), 346, and in the publications cited therein.

Furthermore, German patent documents nos. 100 05 555, 100 06 035, and 100 17 422 discuss encapsulation methods in which a thick, stable silicon layer is used as the cap or cover layer. The object of the methods described in these Offenlegungsschriften was to stabilize the cover layer by using a suitable material (epi-polysilicon in all three cases) having an adequate layer thickness. However, all methods have the disadvantage that cover layers of an adequate thickness may be reliably produced only at great cost and with substantial technical difficulty (for example, topography, mask alignment for photolithography, vertical path resistances due to doping profiles, lack of homogeneity in depth structuring of the thick membrane layer (formation of pockets in the case of trenches), etc.).

The disadvantage of the encapsulation methods which form a thin cap layer is poor cap stability toward stresses during mounting in plastic packages. For example, an overpressure which may damage the thin cap layer is applied to the material during transfer-molding of the sensors.

### SUMMARY OF THE INVENTION

The exemplary embodiment and/or exemplary method of the present invention provides a micromechanical component and a method for the manufacture thereof, a micromechanical component structure being hermetically sealable by a cap structure using only relatively thin cover layers. In addition, the component may be packaged in very small standard plastic packages, such as PLCC, SOIC, QFN, MLF and CSP.

The exemplary embodiment and/or exemplary method of the present invention improves the functionality of micromechanical sensors, since parasitic capacitances are reduced, providing greater freedom for the analyzer circuit. A further advantage of the exemplary embodiment and/or exemplary method of the present invention is that it provides a simple manner of system-in-package integration, the system function being testable on the wafer level.

The exemplary embodiment and/or exemplary method of the present invention involves the manufacture of a chip having a cap structure over a chip structure according to an available method, a thin cover layer being sufficient—unlike the related art—because the hermetically encapsulated chip is mounted according to the exemplary embodiment and/or exemplary method of the present invention on a substrate, e.g., an analyzer IC, by chip-on-wafer flip-chip assembly with the contact side facing down. In the case of flip-chip assembly, an underfill (using plastic molding compound/adhesive) is provided between the chip and the substrate after bonding and forms the connection between the flip chips and the substrate in the usual manner. After curing, the underfill also stabilizes the thin cap structure of the encapsulated chip, in such a way that the sensor structure is hermetically protected with a high degree of reliability against environmental influences and, in particular, against high insertion pressure during subsequent mold-packaging.

Following chip-on-wafer flip-chip assembly, the chip/substrate system may be pretested via metal contacts which are located on the substrate or the chip. During subsequent sawing, the chips are protected by the substrate, which may be thick, while the back is hermetically embedded in the underfill. During further processing, the chip/substrate system is packaged in plastic as standard procedure.

The high stability despite thin film sensor encapsulation saves money during the sensor process, thus simplifying the sensor technology. This makes allows for eliminating a dense support structure of the cap layer, or the density of the supports may be substantially reduced, thereby achieving higher basic capacitances without changing the chip area. The system may be pretested on the wafer level. Low parasitic capacitances in the electric connection improve functionality.

The thickness of the sensor wafer may be reduced to nearly any thickness after encapsulation, for example by precision grinding or chemical mechanical polishing, since the cap is stable in the CMP step. The package may have a compact arrangement. Compatibility with customers is ensured, since standard plastic packages may be used. The slightly higher costs of the more complex flip-chip assembly are offset by savings in sensor production.

According to an exemplary embodiment, the mounting area is a metal plating area, the mounting arrangement including solder bumps for flip-chip assembly.

According to another exemplary embodiment, the substrate is an IC chip.

According to another exemplary embodiment, the chip is a sensor chip and/or actuator chip which has a sensor structure and/or actuator structure beneath the encapsulated chip area.

According to another exemplary embodiment, the substrate is mounted on a lead frame, the component being surrounded by a plastic package.

According to another exemplary embodiment, the encapsulated chip area has a cap-type cover for covering a functional area provided on a substrate, the cap-type cover having at least one perforated cover layer , and the cover layer being sealed by at least one sealing layer.

Although it is applicable to any micromechanical component and structure, in particular sensors and actuators, the exemplary embodiment and/or exemplary method of the present invention and its underlying objective are explained in relation to a micromechanical component, e.g., an acceleration sensor, which may be manufactured on the basis of silicon surface micromechanical technology.

### BRIEF DESCRIPTION OF THE DRAWINGS

FIG. 1 shows a sensor chip in the form of a micromechanical acceleration sensor, which is used in one exemplary embodiment of the present invention.

FIG. 2 shows a representation of an IC wafer and a sensor chip to be mounted thereon according to the exemplary embodiment of the present invention.

FIG. 3 shows a later phase of the process according to the exemplary embodiment of the present invention.

FIG. 4 shows the packaging of separated sensor chip/IC chip pairs in a plastic package according to the exemplary embodiment of the present invention.

### DETAILED DESCRIPTION

In the figures, identical reference numbers designate identical or functionally equivalent components.

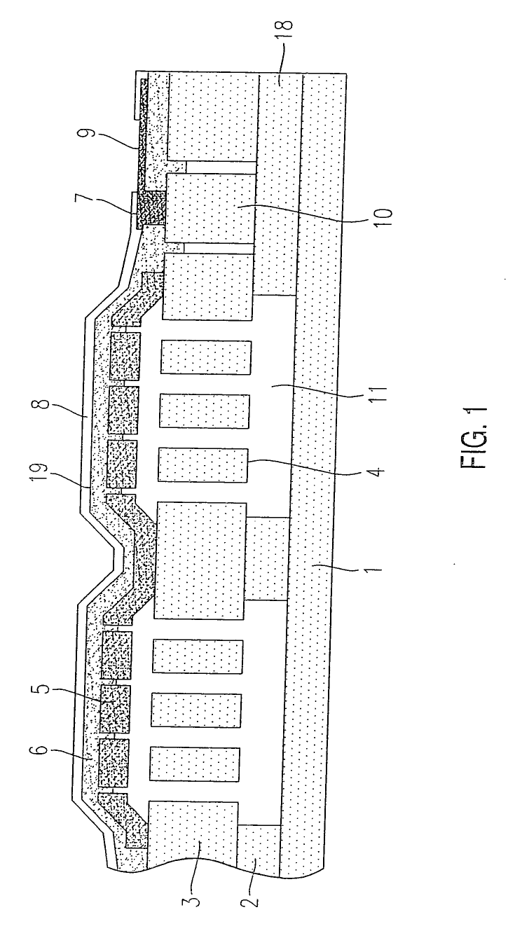

FIG. 1 shows a sensor chip in the form of a micromechanical acceleration sensor, which is used in a first exemplary embodiment of the present invention.

In FIG. 1, reference number 1 identifies a relatively thick silicon substrate wafer, which, however, is not drawn to scale in FIG. 1. Reference number 2 is a silicon dioxide sacrificial layer; 3 is a functional layer made of epi-polysilicon; 4 is a movable structure, for example electrode fingers; 5 is a perforated cap layer, e.g., made of epi-polysilicon or LPCVD silicon which is typically 2 μm to 10 μm thick and seals a cavity 11 in which the sensor structure is embedded. Reference number 6 designates a sealing layer made, for example, of silicon dioxide, silicon nitride, BPSG, PSG or a similar material which is typically 2 μm to 8 μm thick. Reference number 7 designates a metal plating layer which has an open metal contact surface 9 for solder bumps for the purpose of flip-chip bonding. Reference number 8 designates a passivation layer made, for example, of silicon dioxide or silicon nitride which is typically 200 nm to 1.5 μm thick. Reference number 10 designates contact blocks which contact a conductor path level (not illustrated), which, in turn, connects to electrode fingers 4.

In FIG. 1, reference number 18 designates the sensor chip as a whole and reference number 19 the encapsulated chip area which is higher than its vicinity.

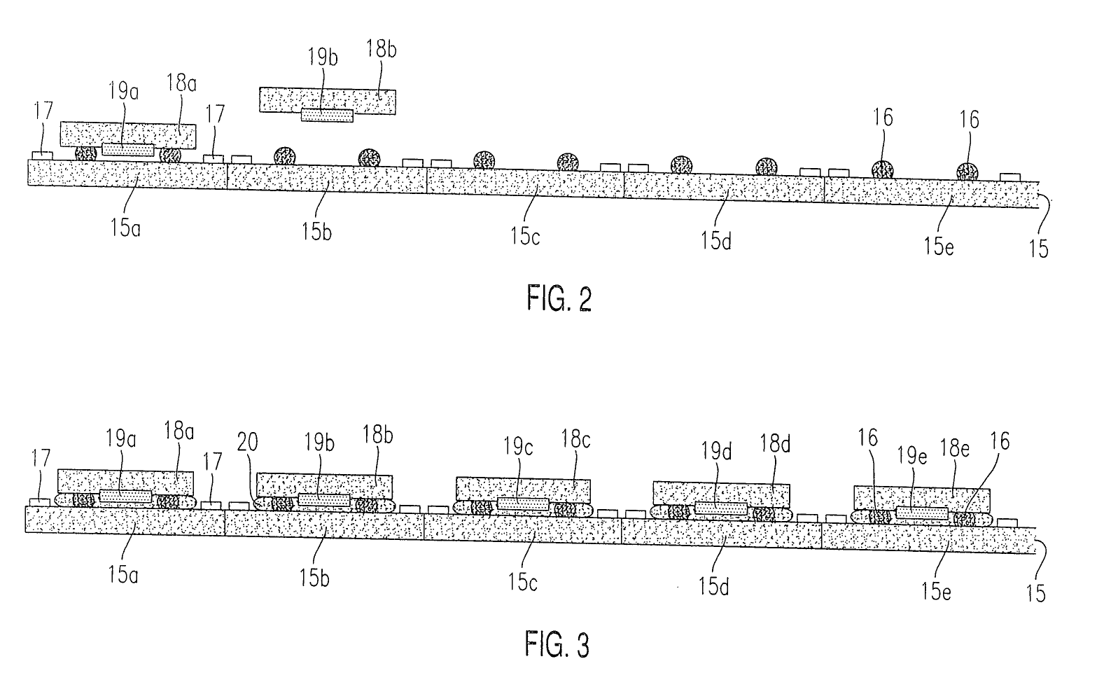

FIG. 2 shows a representation of an IC wafer and sensor chips to be mounted thereon according to the exemplary embodiment of the present invention.

In FIG. 2, reference number 15 designates the IC wafer as a whole. IC wafer 15 includes a plurality of IC chips 15a through 15e. On IC chips 15a through 15e, solder bumps 16 are prepared ahead of time in the usual manner for a standard flip-chip process. IC chips 15a through 15e are usually slightly larger than sensor chips 18a, 18b, etc. having encapsulated areas 19a, 19b, etc. Contact pads 17 on IC chips 15a through 15e may therefore be provided outside the area having solder bumps 16, which are used later on for pretesting or wire-bonding during packaging.

The representation in FIG. 2 shows the process for mounting sensor chips 18a, 18b, etc., which may also be pretested separately in the usual manner, on IC chips 15a through 15e, which are still bonded to the wafer and may also be pretested separately to complete flip-chip assembly. According to this flip-chip assembly of sensor chips 18a, 18b, etc., the sensor chips are mounted in such a way that encapsulated chip area 19a, 19b, etc. is surrounded by solder bumps 16 and is positioned at a distance from the surface of IC chips 15a through 15e. In this regard, solder bumps 16 may be provided on sensor chips 18a, 18b, etc. instead of on IC chips 15a through 15e.

FIG. 3 shows a later phase of the process according to the exemplary embodiment/method of the present invention.

According to FIG. 3, all sensor chips 18a through 18e are now flip-chip-bonded to corresponding IC chips 15a through 15e. Following flip-chip bonding, an underfill 20 made of a plastic molding compound or a plastic adhesive is placed in the gap between a particular sensor chip 18a through 18e and associated IC chips 15a through 15e. This is usually carried out via a dispensing step in which capillary forces draw the underfill between sensor chips 18a through 18e and IC chips 15a through 15e. Underfill 20 is then cured, and it increases the stability of the flip-chip bond. In addition, underfill 20 stabilizes the thin cap membrane during later assembly in the plastic package. After underfill 20 has been cured, the system may be pretested on the wafer level, since electric contacts 17 are freely accessible.

The main advantage of underfill 20 is that it may be applied largely without overpressure and therefore places no stress on the encapsulation. After curing, the underfill stabilizes the encapsulation in that, during injection molding, it is supported on the stationary sensor areas or the surrounding area against the mold pressure. In addition to traditional underfill materials, any materials may be used which are initially applicable without pressure and then curable in a subsequent crosslinking step (heat-curing, cross-linking by moisture, etc.). The thermal expansion coefficient of underfill 20 is advantageously matched to that of the silicon of the sensor chip or IC chip.

In another method step, the sensor chip/IC chip pairs may finally be separated by a sawing process.

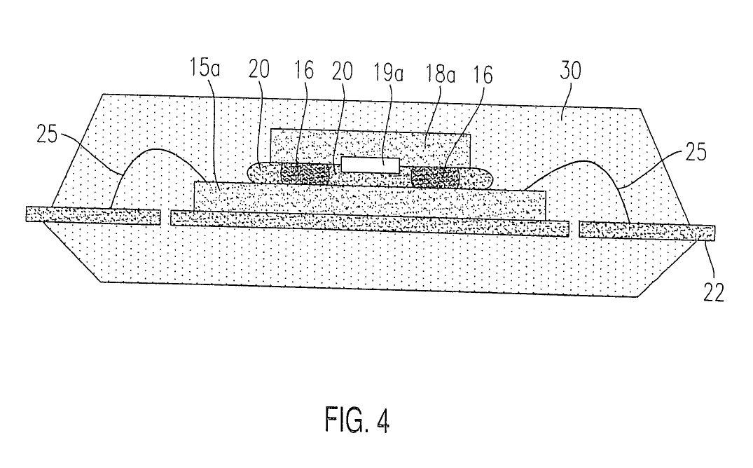

FIG. 4 shows the packaging of the separated sensor chip/IC chip pairs in a plastic package according to the exemplary embodiment of the present invention.

In FIG. 4, reference number 22 designates a lead frame on which the IC chip/Sensor chip pair is mounted, for example by soldering. Reference number 25 identifies bonds from the inner area of lead frame 22 to the outer area. Reference number 30 designates the plastic package which is molded around the assembly structured in this manner. Very high hydrostatic pressures of up to 100 bar occur during molding. During this process, underfill 20 protects the thin sensor encapsulation and absorbs the pressure. The sensor structure is protected on top by substrate wafer 1. Substrate deflection is minimal and determines the maximum expansion of the thin sensor encapsulation. In addition, solder bumps 16 act as rigid spacers and reduce the deflection of the sensor chip and thus also that of the thin sensor encapsulation. Solder bumps 16 are advantageously positioned in such a way that a predefined sensor chip structure ensures optimum stability. In this assembly, the sensor structure is hermetically protected against environmental influences and high pressures. In addition, the thermal expansion coefficients of the underfill and plastic package 30 are matched to each other to the extent possible. As a result, no critical strains occur later on during changes in temperature.

Although the present invention was described above on the basis of an exemplary embodiment(s), it is not limited thereto, but is modifiable in a number of different ways.

In particular, any micromechanical base materials may be used, and not only the silicon substrate described by way of example.

The exemplary method according to the present invention may be used, in particular, for any sensor and actuator elements manufactured by surface micromechanical or bulk micromechanical methods. For example, sensor or actuator structures having an integrated analyzer circuit may be mounted on a chip and the latter may be packaged with a further ASIC.

Although the mounting area in the above example is a metal plated area and the mounting arrangement includes solder bumps for flip-chip assembly, other assembly types, for example anisotropic or isotropic adhesion or thermocompression welding, etc. may also be used.

The list of reference numbers is as follows:

1 Substrate wafer

2 Sacrificial layer

3 Polysilicon functional layer

4 Electrode fingers

5 Cap layer

6 Sealing layer

7 Contact pad

8 Passivation layer

9 Metal contact surface

10 Contact spot

11 Cavity

15; 15a-e Substrate, IC wafer

16 Solder bumps

17 Contact pads

18; 18a-e Sensor chips

19; 19a-e Encapsulated area

20 Underfill

22 Lead frame

25 Bonding wire

30 Plastic package

1-17. (canceled)

18. A micromechanical component comprising:
a chip mounted on a substrate, and having an encapsulated chip area which is higher than its vicinity, a mounting area being provided in a vicinity of the encapsulated chip area;
wherein the chip is mounted on the substrate using a mounting arrangement which is connected to the mounting area, so that the encapsulated chip area faces the substrate and is positioned at a distance therefrom, the encapsulated chip area being surrounded by an underfill beneath the chip.

19. The micromechanical component of claim 18, wherein the mounting area includes a metal-plated area, and the mounting arrangement includes solder bumps for a flip-chip assembly.

20. The micromechanical component of claim 18, wherein the mounting area includes an adhesive area, and the mounting arrangement includes an adhesive arrangement.

21. The micromechanical component of claim 18, wherein the mounting area includes a welding area, and the mounting arrangement includes a welding zone.

22. The micromechanical component of claim 18, wherein the substrate includes an integrated circuit chip.

23. The micromechanical component of claim 18, wherein the chip includes at least one of a sensor chip, an actuator chip which has a sensor structure, and an actuator structure beneath the encapsulated chip area.

24. The micromechanical component of claim 18, wherein the substrate is mounted on a lead frame, and the component is surrounded by a plastic package.

25. The micromechanical component of claim 18, wherein the encapsulated chip area includes a cap-type cover for covering a functional area provided on a substrate, the cap-type cover having at least one perforated cover layer which is sealed by at least one sealing layer.

26. A method for making a micromechanical component, the method comprising:
providing a chip which includes an encapsulated chip area which is higher than its vicinity, and a mounting area in a vicinity of the encapsulated chip area;
mounting the chip on a substrate via a mounting arrangement, which is connected to the mounting area, so that the encapsulated chip area faces the substrate and is positioned at a distance therefrom; and
underfilling the chip so that the encapsulated chip area is surrounded by an underfill beneath the chip.

27. The method of claim 26, wherein the mounting area includes a metal-plated area, and the mounting arrangement includes solder bumps for a flip-chip assembly.

28. The method of claim 26, wherein the mounting area includes an adhesive area, and the mounting arrangement includes an adhesive arrangement.

29. The method of claim 26, wherein the mounting area includes a welding area, and the mounting arrangement includes a welding zone.

30. The method of claim 26, wherein the substrate includes an integrated circuit chip.

31. The method of claim 30, wherein a plurality of chips are mounted on a plurality of wafer-bonded IC chips, and the components are subsequently separated.

32. The method of claim 26, wherein the chip includes at least one of a sensor chip, an actuator chip which has a sensor structure, and an actuator structure beneath the encapsulated chip area.

33. The method of claim 26, wherein the substrate is mounted on a lead frame, and the component is surrounded by a plastic package.

34. The method of claim 26, wherein the encapsulated chip area includes a cap-type cover for covering a functional area provided on the substrate, the cap-type cover including at least one perforated cover layer which is sealed by at least one sealing layer.
